(19) United States
(12) Patent Application Publication
(10) Pub. No.: US 2026/0229379 A1
(43) Pub. Date: Aug. 6, 2026

(54) METHOD FOR MANUFACTURING A NUCLEAR FUEL ROD CLADDING AND CORRESPONDING NUCLEAR FUEL ROD CLADDING

(71) Applicant: FRAMATOME, COURBEVOIE (FR)

(72) Inventors: Karl BUCHANAN, CHASSIEU (FR); Jérémy BISCHOFF, LYON (FR); Philippe LEGRAND, PORNICHET (FR)

(21) Appl. No.: 19/151,063

(22) PCT Filed: Jan. 26, 2024
(86) PCT No.: PCT/EP2024/051877

§ 371 Date: Jul. 25, 2025

(30) Foreign Application Priority Data
Jan. 27, 2023 (FR) FR2300769

(51) Int. Cl. G21C 21/02; G21C 3/06

(52) U.S. Cl. CPC G21C 21/02; G21C 3/06

(57) ABSTRACT

A method for manufacturing a nuclear fuel rod cladding and corresponding nuclear fuel rod cladding, the method being intended for the manufacture of a cladding of a nuclear fuel rod comprising a substrate covered with a protective coating. The method for manufacturing includes the provision of the substrate and the deposition of the protective coating on the substrate by physical vapor deposition by cathodic sputtering, by implementing simultaneously several different techniques of physical vapor deposition by cathodic sputtering.

### CROSS-REFERENCE TO RELATED APPLICATIONS

This application is the U.S. National Phase of PCT Appl. No. PCT/EP2024/051877 filed Jan. 26, 2924, which claims priority to FR 23 00769, filed Jan. 27, 2023, the entire disclosures of which are incorporated by reference herein.

### TECHNICAL FIELD

The present disclosure relates to the field of nuclear fuel rod claddings (hereinafter also referred to as “claddings”) intended to contain nuclear fuel.

### BACKGROUND

The nuclear fuel including the fissile material is generally contained in a cladding that prevents the dispersion of the nuclear fuel.

Nuclear fuel assemblies used in light water or heavy water reactors generally comprise a bundle of nuclear fuel rods, each nuclear fuel rod comprising a tubular cladding containing nuclear fuel, the cladding being sealed at each of its two ends by a plug.

Nuclear fuel rod claddings are made, for example, of zirconium-based alloy. Such zirconium-based alloys present high performance under normal operating conditions in nuclear reactors.

However, they can reach their limits, notably in terms of temperature, during severe accidental conditions, for example, during a Loss Of Coolant Accident (LOCA).

During such an event, the temperature in the core of the nuclear reactor can exceed 800° C., and the coolant present is then essentially in the form of steam.

This can cause rapid degradation of the nuclear fuel rod cladding, with notably a release of hydrogen and rapid oxidation of the cladding, leading to its embrittlement or even rupture, and thus the release of nuclear fuel out of the cladding.

It is possible to provide a cladding comprising a substrate made of zirconium-based alloy and covered with a protective coating made, for example, of a chrome-based material.

Such a protective coating generally allows the tolerance of the cladding under normal and accidental conditions to be increased.

It is possible to manufacture such a cladding by depositing the protective coating on the substrate by physical vapor deposition.

However, such a technique for depositing the protective coating is relatively slow, in particular, for significant coating thicknesses.

The widespread use of protective coatings on nuclear fuel claddings at the industrial level requires the ability to carry out the deposition of the protective coating quickly enough.

### SUMMARY

One of the aims of the present disclosure is to propose a method for manufacturing a nuclear fuel cladding having a substrate coated with a protective coating, which can be implemented quickly.

To this end, the present disclosure proposes a method for manufacturing a nuclear fuel rod cladding comprising a substrate covered with a protective coating, the method for manufacturing comprising the provision of the substrate, and the deposition of the protective coating on the substrate by physical vapor deposition by cathodic sputtering, by implementing simultaneously several techniques of physical vapor deposition by cathodic sputtering, different from one another.

The simultaneous implementation of several different techniques of physical vapor deposition by cathodic sputtering allows to carry out a rapid deposition of the protective coating, obtaining a protective coating having good resistance to the external environment and good adhesion to the substrate.

The “simultaneous” implementation means that the different techniques of physical vapor deposition are implemented together and at the same time, that is, during the same period of time.

The different techniques of physical vapor deposition by cathodic sputtering implemented simultaneously can be implemented by using at least one common cathode to at least two from among the different techniques of physical vapor deposition by cathodic sputtering implemented simultaneously and/or at least one dedicated cathode to only one from among the different techniques of physical vapor deposition by cathodic sputtering implemented simultaneously.

Each physical vapor deposition technique is implemented by applying an excitation signal to the associated cathode, the excitation signal presenting a periodic pattern, the pattern being, for example, a plateau, a pulse, or a train of pulses.

The joint implementation of several different techniques of physical vapor deposition using the same common cathode is, for example, carried out by combining the excitation signals emitted simultaneously and in a synchronized manner in such a way that their respective patterns are applied sequentially to the common cathode.

According to particular embodiments, the method for manufacturing comprises one or more of the following optional features, taken individually or in any technically possible combination:
at least two from among the different techniques of physical vapor deposition by cathodic sputtering are implemented simultaneously using a common cathode;
the method for manufacturing comprises applying to each common cathode a combined excitation signal corresponding to the superposition of at least two elementary excitation signals, each elementary excitation signal being formed of a periodic pattern corresponding to a respective technique of physical vapor deposition by cathodic sputtering from among the techniques of physical vapor deposition by cathodic sputtering implemented simultaneously using said common cathode, the elementary excitation signals being synchronized in such a way that their respective patterns are present sequentially in the combined excitation signal;
each elementary excitation signal is generated by a respective excitation signal generator, the elementary excitation signals being synchronized and superposed to form the combined excitation signal applied to said common cathode;
at least one from among the techniques of physical vapor deposition by cathodic sputtering implemented simultaneously is implemented using a dedicated cathode, by applying to this dedicated cathode an excitation signal for the implementation of this technique of physical vapor deposition;
each from among the techniques of physical vapor deposition by cathodic sputtering implemented simultaneously is implemented using a dedicated cathode, by applying to this dedicated cathode an excitation signal for the implementation of this technique of physical vapor deposition;
the excitation signal of each dedicated cathode is generated by a respective excitation signal generator;
the technique of physical vapor deposition implemented simultaneously are chosen from among the high power impulse magnetron sputtering (HiPIMS) unipolar or bipolar, the direct current (DC) magnetron sputtering unipolar or bipolar, the pulsed direct current (pulsed-DC) magnetron sputtering unipolar or bipolar, the medium frequency (MF) magnetron sputtering unipolar or bipolar, and the radio frequency (RF) magnetron sputtering unipolar or bipolar;
the substrate is made of a zirconium-based material and/or the protective coating is made of a chrome-based material;
the thickness of the protective coating at the end of the deposition step is comprised between 5 μm and 30 μm, particularly between 10 μm and 20 μm;
the substrate presents a shape of revolution around a central axis, the method for manufacturing comprising the rotation of the substrate around the central axis during the deposition step;
the method for manufacturing comprises the polarization of the substrate during the deposition of the coating.

The present disclosure also relates to a nuclear fuel rod cladding comprising a substrate covered with a protective coating deposited on the substrate by physical vapor deposition by implementing simultaneously a plurality of different techniques of physical vapor deposition by cathodic sputtering.

The present disclosure also relates to a physical vapor deposition installation, the installation comprising a chamber, at least one atmosphere control device to generate a rarefied atmosphere in the chamber, at least one cathode, and an excitation device, the installation being configured for the deposition of a protective coating on a substrate introduced into the chamber by implementing simultaneously several different techniques of physical vapor deposition techniques by cathodic sputtering using the cathode(s).

According to particular embodiments, the installation comprises one or more of the following optional features, taken individually or in any technically possible combination:
the installation comprises at least one common cathode for the simultaneous implementation of at least two from among the techniques of physical vapor deposition by cathodic sputtering implemented simultaneously, the excitation device being configured to generate a combined excitation signal of the common cathode which corresponds to the superposition of several elementary excitation signals, each elementary excitation signal having a periodic pattern corresponding to a respective from among the techniques of physical vapor deposition by cathodic sputtering implemented simultaneously using said common cathode, the elementary excitation signals being combined in such a way that their respective patterns are present sequentially in the combined excitation signal;
the installation comprises at least one dedicated cathode for the implementation of one from among the techniques of physical vapor deposition by cathodic sputtering implemented simultaneously, the excitation device being configured to generate a respective excitation signal for each dedicated cathode, the excitation signals corresponding to the technique of physical vapor deposition by cathodic sputtering associated with this dedicated cathode.
the installation is configured for the polarization of the substrate during the deposition of the coating.

### BRIEF DESCRIPTION OF THE DRAWINGS

The present disclosure and its advantages will be better understood by studying the following description, given solely by way of non-limiting example, and made with reference to the appended drawings, in which:

FIG. 1 is a schematic longitudinal sectional view of a nuclear fuel rod possessing a cladding;

FIG. 2 is a schematic cross-sectional view of the cladding of the nuclear fuel rod of FIG. 1;

FIG. 3 is a schematic view of an installation for the deposition of a coating on a substrate by physical vapor deposition by cathodic sputtering, comprising a common cathode to two physical vapor deposition techniques by cathodic sputtering implemented simultaneously.

FIG. 4 contains graphs illustrating the realization of a combined excitation signal for the excitation of a cathode for the implementation of a physical vapor deposition by cathodic sputtering;

FIG. 5 contains graphs illustrating the realization of a combined excitation signal for the excitation of a cathode for the implementation of a physical vapor deposition by cathodic sputtering;

FIG. 6 is a schematic view of another deposition installation of a coating on a substrate by physical vapor deposition by cathodic sputtering, the installation comprising two dedicated cathodes, each one provided for the implementation of a respective physical vapor deposition technique by cathodic sputtering.

### DETAILED DESCRIPTION

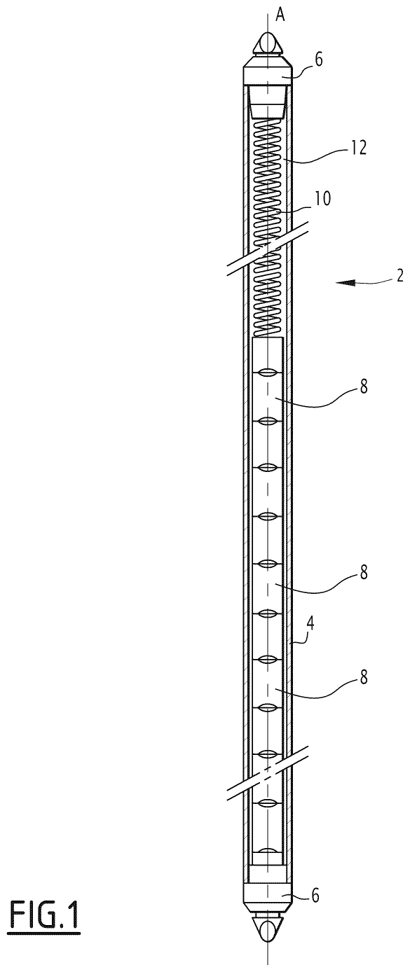

FIG. 1 illustrates a nuclear fuel rod 2 intended to be used in a light water reactor, particularly a pressurized water reactor (PWR) or a boiling water reactor (BWR), a “VVER” type reactor, an “RBMK” type reactor, or a heavy water reactor, for example of the “CANDU” type.

The nuclear fuel rod 2 presents an elongated shape according to a longitudinal axis A.

The nuclear fuel rod 2 comprises a cladding 4 containing nuclear fuel.

The cladding 4 is tubular and extends according to the longitudinal axis A.

The cladding 4 is closed in a sealed manner at each of its ends by a respective plug 6.

The nuclear fuel presents, for example, in the form of a stack of pellets 8 axially stacked inside the cladding 4, each pellet 8 containing fissile material. The stack of pellets 8 is also called a “fissile column”.

The nuclear fuel rod 2 comprises a spring 10 arranged inside the cladding 4, between the stack of pellets 8 and one of the plugs 6, to push the stack of pellets 8 toward the other plug 6. A void or plenum 12 is preferably present between the stack of pellets 8 and the plug 6 on which the spring 10 rests.

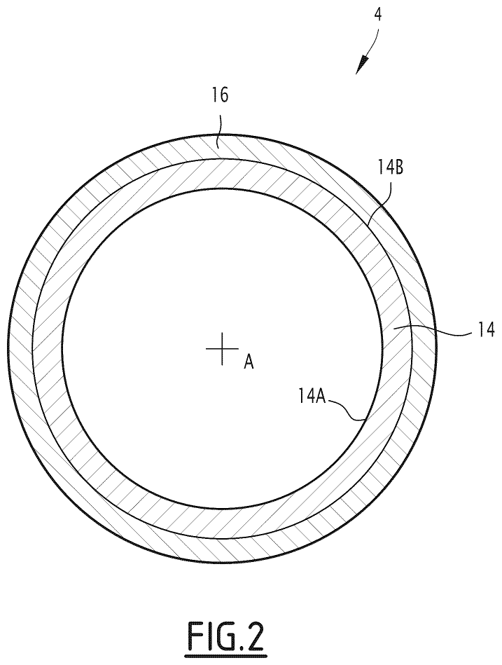

FIG. 2 represents a cross-sectional view of the cladding 4.

The cladding 4 comprises a substrate 14 provided with a protective coating 16.

The substrate 14 is tubular and extends according to the longitudinal axis A. In other words, the substrate 14 is a straight tube the central axis of which is the longitudinal axis A.

The substrate 14 presents, for example, an external diameter comprised between 8 mm and 15 mm, particularly between 9 mm and 13 mm, and/or a length comprised between 1 m and 5 m, particularly between 2 m and 5 m.

The substrate 14 is made of pure zirconium or a zirconium-based alloy.

The expression “pure zirconium” refers to a material containing at least 99% by weight of zirconium, and the expression “zirconium-based alloy” refers to an alloy containing at least 95% by weight of zirconium.

The zirconium-based alloy is, for example, chosen from among one of the known alloys such as M5, ZIRLO, E110, HANA, N36, Zircaloy-2, and Zircaloy-4.

The substrate 14 presents an internal surface 14A turned toward the inside of the substrate 14 and an external surface 14B turned toward the outside of the substrate 14. The internal surface 14A delimits the space for receiving the nuclear fuel. The external surface 14B is opposite the internal surface 14A.

The protective coating 16 covers the external surface 14B of the substrate 14.

The purpose of the protection coating 16 is to protect the external surface 14B of the substrate 14 from the external environment. In the absence of the protective coating 16, the external surface 14B of the cladding 14 would be exposed to the external environment.

The protective coating 16 is made, for example, of a chrome-based material.

The expression “chrome-based material” refers to a material in pure chrome or a chrome-based alloy. A pure chrome material here refers to a material comprising at least 99% by weight of chrome. A chrome-based alloy here refers to an alloy comprising at least 80% by weight of chrome.

The thickness of the protective coating 16 is preferably comprised between 5 μm and 30 μm, particularly between 10 μm and 20 μm.

A method for manufacturing the cladding 4 comprises the provision of the substrate 14 and the deposition of the protective coating 16 on the substrate 14 by physical vapor deposition by implementing simultaneously several techniques of physical vapor deposition by cathodic sputtering, different from each other.

The physical vapor deposition by cathodic sputtering of a coating on a substrate is carried out by generating an electric field using a cathode (or “target”) arranged in a chamber containing a rarefied atmosphere formed, for example, of a neutral gas, such as argon, the electric field causing the appearance in the chamber of a plasma containing atoms and electrically charged particles (electrons, ions . . . ) that are precipitated onto the cathode under the effect of the electric field and detach atoms from the cathode (that is, the cathode is sputtered, hence the expression cathodic sputtering), these atoms detached from the cathode then going to deposit on the substrate. Optionally, a reactive gas, such as dinitrogen or dioxygen, is present in the rarefied atmosphere.

Advantageously, a physical vapor deposition by cathodic sputtering is carried out by magnetron sputtering.

The physical vapor deposition by magnetron cathodic sputtering of a coating on a substrate is carried out by generating an electric field and a magnetic field using a cathode (composed of a “target” and a “magnetron”) arranged in a chamber containing a rarefied atmosphere formed, for example, of a neutral gas, such as argon, the electromagnetic field causing the appearance in the chamber of a plasma containing atoms and electrically charged particles (electrons, ions . . . ) that are precipitated on the cathode under the effect of the electromagnetic field and detach atoms from the cathode (that is, the cathode is sputtered, hence the expression cathodic sputtering), these atoms detached from the cathode then going to deposit on the substrate.

The magnetron comprises, for example, one or more permanent magnets and/or one or more electromagnets.

The provision of a magnetic field allows better control of the trajectory of the electrically charged particles reaching the cathode, which allows better control of a deposition speed of the coating, particularly to obtain a higher deposition speed of the coating.

In the following, unless otherwise stated, the expressions “deposition technique” and “physical vapor deposition technique” refer to physical vapor deposition techniques by cathodic sputtering, possibly magnetron.

The method for manufacturing the cladding 4 thus comprises the simultaneous implementation of several different physical vapor deposition techniques by cathodic sputtering to deposit the protective coating 16 on the substrate 14.

The physical vapor deposition techniques are implemented simultaneously using at least one common cathode to at least two from among the physical vapor deposition techniques implemented simultaneously and/or at least one dedicated cathode, each dedicated cathode being used for the implementation of only one from among the physical vapor deposition techniques implemented simultaneously.

Preferably, when several cathodes are used for the simultaneous implementation of different physical vapor deposition techniques, these cathodes are made of the same material.

In one embodiment, at least two from among the different physical vapor deposition techniques are implemented simultaneously using a common cathode, by applying to this common electrode a combined excitation signal corresponding to the superposition of several elementary excitation signals, each elementary excitation signal corresponding to one of the physical vapor deposition techniques implemented simultaneously using said common electrode.

Each elementary excitation signal has, for example, a periodic pattern, the pattern being, for example, a plateau, a pulse, or a train of pulses.

The combined excitation signal is obtained, for example, by emitting the elementary excitation signals simultaneously and in a synchronized manner in such a way that the respective patterns of the elementary excitation signals are present sequentially in the combined excitation signal, the respective patterns of the elementary excitation signals being applied sequentially to the common cathode.

In the combined excitation signal, the pattern of each elementary excitation signal is present in time windows distinct from those of the pattern of each other elementary excitation signal forming the combined excitation signal. The pattern of each elementary excitation signal is present in time windows dedicated to this elementary excitation signal, to the exclusion of the patterns of the other elementary excitation signals.

Patterns of different elementary excitation signals are not present at the same time in the combined excitation signal.

In one embodiment, a first physical vapor deposition technique and a second physical vapor deposition technique are implemented simultaneously using a common cathode by applying to this common cathode a combined excitation signal corresponding to the superposition of a first elementary excitation signal and a second elementary excitation signal, the first elementary excitation signal corresponding to the first physical vapor deposition technique and the second elementary excitation signal corresponding to the second physical vapor deposition technique, the first elementary excitation signal and the second elementary excitation signal being synchronized in such a way that their respective elementary patterns are alternated in the combined excitation signal.

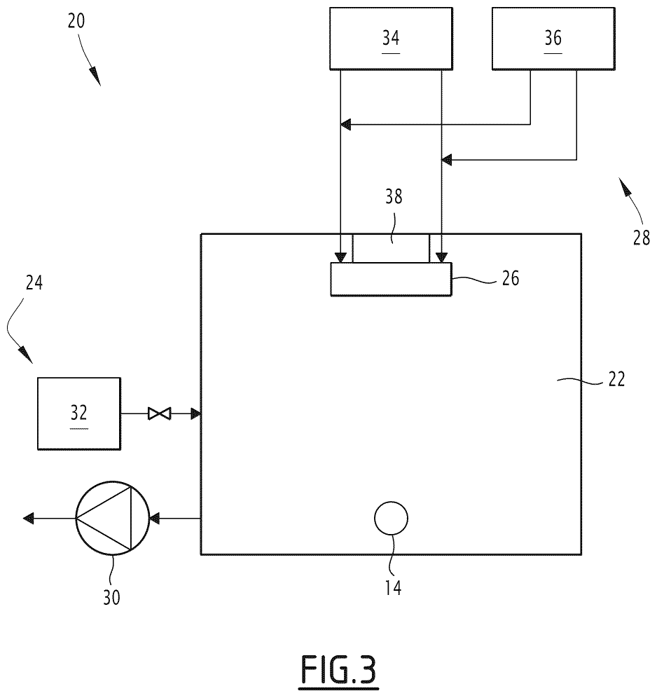

As illustrated in FIG. 3, a physical vapor deposition installation 20 by cathodic sputtering configured for the simultaneous implementation of several different physical vapor deposition techniques using a common cathode, and in particular for the simultaneous implementation of a first physical vapor deposition technique and a second physical vapor deposition technique are implemented simultaneously using a common cathode.

The installation 20 comprises a chamber 22 to receive one or more substrates 14, an atmosphere control device 24 to generate a rarefied atmosphere in the chamber 22, a common cathode 26, and an excitation device 28 connected to the common cathode 26.

The atmosphere control device 24 comprises, for example, a pumping device 30 connected to the chamber 22 to generate a rarefied atmosphere in the chamber 22 and a gas supply device 32 fluidly connected to the chamber 22 to provide a neutral gas, for example, argon and/or a reactive gas, for example, dinitrogen or dioxygen.

The excitation device 28 is configured to generate a combined excitation signal applied to the common cathode 26 and corresponding to the superposition of elementary excitation signals for the implementation of the physical vapor deposition technique.

Each physical vapor deposition technique is implemented by applying an elementary excitation signal to the associated cathode, the elementary excitation signal presenting a repeated periodic pattern, the pattern being, for example, a plateau, a pulse, or a train of pulses.

The superposition of periodic excitation signals is carried out in a synchronized manner in such a way that the respective patterns of the excitation signals are applied sequentially to the cathode.

The excitation device 28 is here configured for the simultaneous implementation of a first physical vapor deposition technique and a second physical vapor deposition technique using the common cathode 26.

The excitation device 28 comprises, for example, a first electrical generator 34 and a second electrical generator 36 connected in parallel to the common cathode 26, the first electrical generator 34 and the second electrical generator 36 being configured to generate respectively a first electrical signal for the implementation of the first physical vapor deposition technique and a second electrical signal for the implementation of the second physical vapor deposition technique, in a synchronized manner.

The installation 20 optionally comprises a magnetic field generator 38 (or magnetron) configured to generate a magnetic field near the common cathode 26, for the implementation of physical vapor deposition techniques by cathodic sputtering called “magnetron” using the common cathode 26.

The magnetic field generator 38 comprises one or more permanent magnets and/or one or more electromagnets.

When the magnetic field generator 38 is active, the first physical vapor deposition technique and the second physical vapor deposition technique, implemented simultaneously, are physical vapor deposition techniques by magnetron cathodic sputtering.

In operation, the atmosphere control device 24 generates a rarefied atmosphere in the chamber 22, and the excitation device 28 generates the combined excitation signal and applies it to the common cathode 26, in such a way that the physical vapor deposition techniques are implemented simultaneously using the common cathode 26.

In particular, in the illustrated example, the first electrical generator 34 and the second electrical generator 36 generate the first elementary excitation signal and the second elementary excitation signal simultaneously, the first elementary excitation signal and the second elementary excitation signal being combined by superposition to generate the combined excitation signal.

If necessary, the magnetic field generator 38 generates a magnetic field near the common cathode 26.

Each of the physical vapor deposition techniques implemented simultaneously is achievable in unipolar mode or bipolar mode.

Subsequently, in the absence of precision, each physical vapor deposition technique is usable in unipolar mode or bipolar mode.

The physical vapor deposition techniques implemented simultaneously are, for example, chosen from among the high power impulse magnetron sputtering (HiPIMS) unipolar or bipolar, the direct current (DC) magnetron sputtering unipolar or bipolar, the pulsed direct current (pulsed-DC) magnetron sputtering unipolar or bipolar, the medium frequency (MF) magnetron sputtering unipolar or bipolar, and the radio frequency (RF) magnetron sputtering unipolar or bipolar.

In one embodiment, the common cathode 26 is used for the simultaneous implementation of a physical vapor deposition by high power impulse magnetron sputtering (HiPIMS) unipolar or bipolar, and a physical vapor deposition by medium frequency (MF) magnetron sputtering unipolar or bipolar.

Optionally, the installation 20 is configured to polarize the substrate 14 during the implementation of the physical vapor deposition. The polarization of the substrate 14 allows the deposition, particularly the quality and density of the deposited coating to be improved. The polarization of the substrate 14 is carried out, for example, using a dedicated substrate 14 polarization generator. The substrate 14 polarization generator is, for example, configured to apply a constant voltage to the substrate, for example, a voltage of the order of 100V.

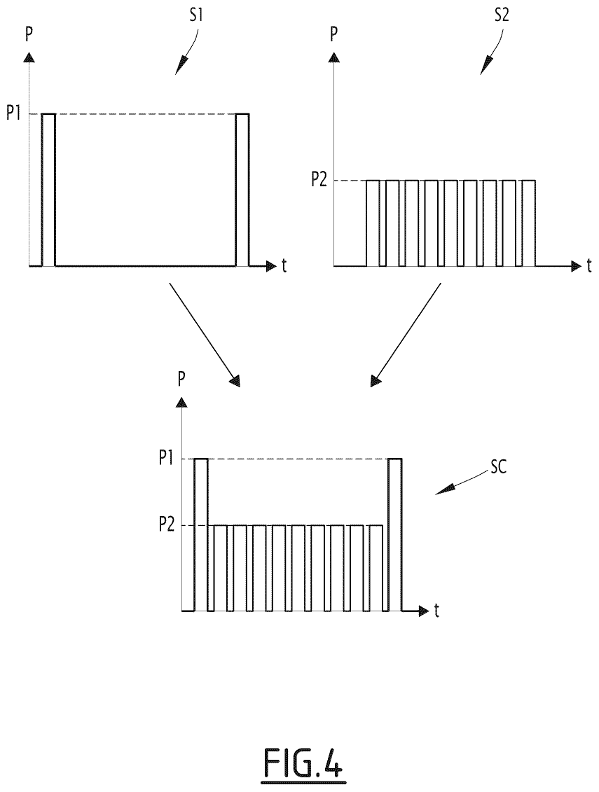

FIG. 4 comprises three graphs representing a first elementary excitation signal S1, a second elementary excitation signal S2, and a combined excitation signal SC resulting from the combination, and more particularly from the superposition of the first elementary excitation signal S1 and the second elementary excitation signal S2, each graph indicating an instantaneous power of the corresponding excitation signal as a function of time.

The first elementary excitation signal S1 is configured for the realization of a physical vapor deposition technique by high power impulse magnetron sputtering.

The first elementary excitation signal S1 is periodic and based on a first pattern formed of a first pulse. The first elementary excitation signal S1 thus comprises first pulses repeated with a first frequency F1 and a first power P1.

The second elementary excitation signal S2 is configured for the realization of a physical vapor deposition technique by medium power magnetron sputtering.

The second elementary excitation signal S2 is periodic and based on a second pattern formed of a train of identical second pulses with a second frequency F2 and having a second power P2. The second elementary excitation signal S2 thus comprises a series of trains of second pulses, each train of second pulses comprising several identical successive pulses with a second frequency F2 and a second power P2.

Only one train of second pulses is represented in FIG. 4. The second elementary excitation signal S2 comprises several successive trains of second pulses.

Preferably, the first frequency F1 is strictly lower than the second frequency F2 and/or the first power P1 is strictly higher than the second power P2.

The duration of a train of second pulses of the second elementary excitation signal S2 preferably corresponds to the duration between a first pulse and the next first pulse of the first elementary excitation signal S1, and the interval between a train of second pulses of the second elementary excitation signal S2 and the next train of second pulses preferably corresponds to the duration of a first pulse of the first elementary excitation signal S1.

The first elementary excitation signal S1 and the second elementary excitation signal S2 are synchronized in such a way that the first pattern and the second pattern are alternated in the combined excitation signal SC.

The superposition of the first elementary excitation signal S1 and the second elementary excitation signal S2 results in a combined excitation signal SC comprising the first pulses at the first power P1 and, between each first pulse and the next first pulse, a train of second pulses at the second power P2.

In the combined excitation signal SC, the first pattern and the second pattern are formed sequentially, the sequence being repeated periodically.

The combined excitation signal SC allows the simultaneous implementation of the first physical vapor deposition technique and the second physical vapor deposition technique.

In particular, the first pulses at the first power P1 and with the first frequency F1 allow the implementation of the first physical vapor deposition technique (physical vapor deposition by high power impulse magnetron sputtering), the time intervals between the first pulses being exploited to implement the second physical vapor deposition technique (physical vapor deposition by medium frequency magnetron sputtering) which requires pulses at the second power P2 lower than the first power P1 with a second frequency F2 higher than the first frequency F1.

In one embodiment, the common cathode 26 is used for the simultaneous implementation of a physical vapor deposition by high power impulse magnetron sputtering (HiPIMS) unipolar or bipolar and a physical vapor deposition by direct current (DC) magnetron sputtering unipolar or bipolar.

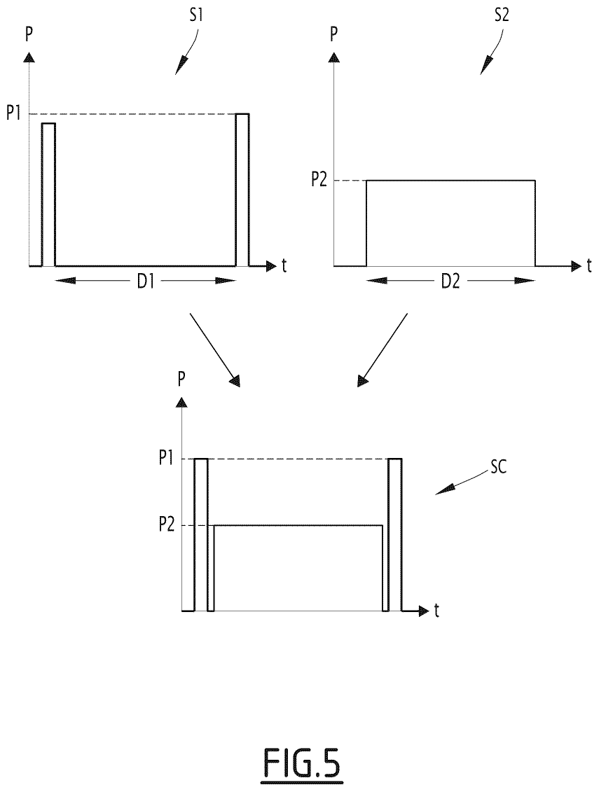

FIG. 5 is similar to FIG. 4 and differs in that the second elementary excitation signal S2 is provided for the realization of a physical vapor deposition technique by direct current magnetron sputtering.

The second elementary excitation signal S2 is periodic and based on a second pattern presenting the form of a second plateau at a second power P2. The second elementary excitation signal S2 thus comprises plateaus at a second power P2, the plateaus being separated by intervals at zero power, the plateaus preferably having a longer duration than that of the intervals.

The spacing between the intervals corresponds to the duration between the first pulses of the first elementary excitation signal S1, and the duration of the intervals corresponds to the duration of the first pulses of the first elementary excitation signal S1.

Preferably, the first power P1 is strictly higher than the second power P2.

The superposition of the first elementary excitation signal S1 and the second elementary excitation signal S2 results in a combined excitation signal SC comprising the first pulses at the first power P1 with a plateau at the second power P2 between each first pulse and the next first pulse.

In the combined excitation signal SC, the first pattern and the second pattern are formed sequentially, the sequence being repeated periodically.

The combined excitation signal SC allows the simultaneous implementation of the first physical vapor deposition technique and the second physical vapor deposition technique.

In particular, the first pulses at the first power P1 and with the first frequency F1 allow the implementation of the first physical vapor deposition technique (physical vapor deposition by high power impulse magnetron sputtering), the time intervals between the first pulses being exploited to implement the second physical vapor deposition technique (physical vapor deposition by direct current magnetron sputtering) which requires a direct current at the second power P2 lower than the first power P1.

In one embodiment, at least one or each from among the physical vapor deposition techniques implemented simultaneously is implemented using a dedicated cathode, by applying between this dedicated cathode and the substrate a specific excitation signal for the implementation of only one physical vapor deposition technique.

Each dedicated cathode is associated with only one physical vapor deposition technique and is distinct from each other cathode, dedicated or common.

In one embodiment, the excitation signal of each dedicated cathode is generated by a respective excitation signal generator.

An excitation device 28 comprises in this case a respective excitation signal generator associated with each dedicated cathode.

In one embodiment, a first physical vapor deposition technique is implemented using a first dedicated cathode, by applying to this first dedicated cathode a first specific excitation signal for the implementation of this first physical vapor deposition technique, and, simultaneously, a second physical vapor deposition technique is implemented using a second dedicated cathode, by applying to this second dedicated cathode a second specific excitation signal for the implementation of this first physical vapor deposition technique.

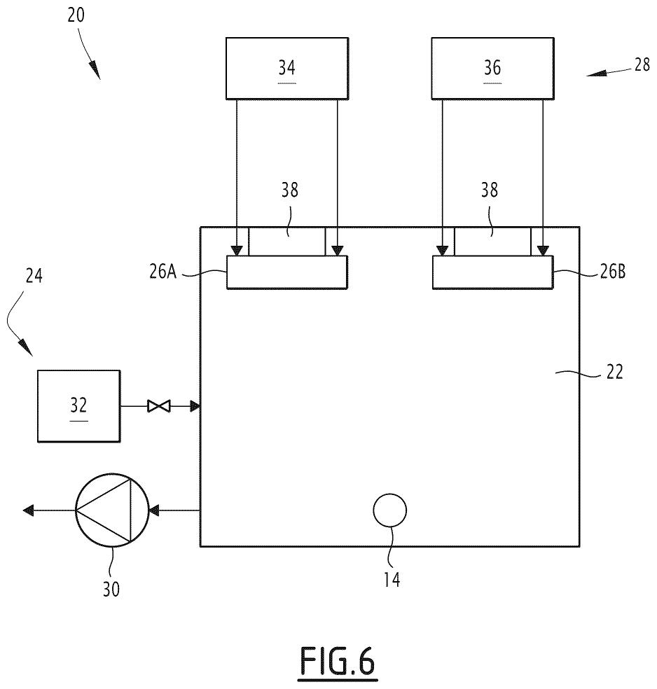

The installation 20 of FIG. 6 differs from that of FIG. 3, the numerical references of which, associated with similar elements are retained, in that the installation 20 comprises a first dedicated cathode 26A for the implementation of a first physical vapor deposition technique by cathodic sputtering and a second dedicated cathode 26B, distinct from the first dedicated cathode 26A, for the implementation of a second physical vapor deposition technique different from the first physical vapor deposition technique.

Preferably, the first dedicated cathode 26A and the second dedicated cathode 26B are made of the same material.

The excitation device 28 is configured to generate simultaneously a first specific excitation signal applied to the first dedicated cathode 26A and a second specific excitation signal applied to the second dedicated cathode 26B.

As illustrated in FIG. 6, the excitation device 28 comprises, for example, a first electrical generator 34 configured to generate the first specific excitation signal and connected to the first dedicated cathode 26A and a second electrical generator 36 configured to generate the second specific excitation signal and connected to the second dedicated cathode 26B.

In operation, the atmosphere control device 24 generates a rarefied atmosphere in the chamber 22, the excitation device 28 generates simultaneously the first specific excitation signal applied to the first dedicated cathode 26A and the second specific excitation signal applied to the second dedicated cathode 26B, so as to implement simultaneously the first physical vapor deposition technique and the second physical vapor deposition technique.

In particular, the first electrical generator 34 and the second electrical generator 36 generate respectively the first specific excitation signal and the second specific excitation signal simultaneously, applied respectively to the first dedicated cathode 26A and to the second dedicated cathode 26B, so as to implement simultaneously the first physical vapor deposition technique and the second physical vapor deposition technique.

If necessary, the magnetic field generator 38 generates a magnetic field near the first dedicated cathode 26A and/or near the second dedicated cathode 26B.

The physical vapor deposition techniques implemented simultaneously are, for example, chosen from among the high power impulse magnetron sputtering (HiPIMS) unipolar or bipolar, the direct current (DC) magnetron sputtering unipolar or bipolar, and the medium frequency (MF) magnetron sputtering unipolar or bipolar.

In one embodiment, the first dedicated cathode 26A is used for the implementation of a high power impulse magnetron sputtering (HiPIMS) unipolar or bipolar, and the second dedicated cathode 26B is used for the implementation of a medium frequency (MF) magnetron sputtering unipolar or bipolar.

In this case, the first specific excitation signal and the second specific excitation signal correspond respectively to the first elementary excitation signal S1 and the second elementary excitation signal S2 of FIG. 3.

In one embodiment, the first dedicated cathode 26A is used for the implementation of a high power impulse magnetron sputtering (HiPIMS) unipolar or bipolar, and the second dedicated cathode 26B is used for the implementation of a direct current (DC) magnetron sputtering unipolar or bipolar.

In this case, the first specific excitation signal corresponds to the first elementary excitation signal S1 of FIG. 3, and the second specific excitation signal is a constant continuous signal at the second power P2.

Preferably, during the physical vapor deposition, the substrate 14, which is tubular according to its longitudinal axis A, is driven in rotation around its longitudinal axis A. This ensures uniform deposition on the circumference of the substrate 14.

To do this, the installation 20 is configured for driving in rotation the substrate 14 around its longitudinal axis A during the physical vapor deposition.

The present disclosure is not limited to the example embodiments and alternatives illustrated and described above.

It is possible to implement simultaneously exactly two physical vapor deposition techniques, using a common cathode or two dedicated cathodes, as illustrated in FIGS. 3 and 6.

More generally, the deposition of the protective coating 16 is carried out by implementing simultaneously one, two, or more than two techniques of physical vapor deposition by cathodic sputtering, using one or more common cathodes and/or one or more dedicated cathodes.

A physical vapor deposition installation 20 for the realization of the deposition of the protective coating 16 thus comprises at least one common cathode 26 and/or at least one dedicated cathode 26A, 26B, the excitation device 28 being able to generate the combined excitation signal applied to each common cathode 26 and the specific excitation signal applied to each dedicated cathode 26A, 26B.

Each common cathode is used to implement a group of physical vapor deposition techniques comprising at least two physical vapor deposition techniques.

Each group of physical vapor deposition techniques comprises, for example, two physical vapor deposition techniques (it is a pair or a couple of physical vapor deposition techniques) or more than two physical vapor deposition techniques.

Each group of physical vapor deposition techniques is different from the other possible group(s) of physical vapor deposition techniques, while possibly being able to contain at least one physical vapor deposition technique common to one or more other groups of physical vapor deposition techniques when several groups of physical vapor deposition techniques are implemented simultaneously, each using a respective common cathode.

Each dedicated cathode is associated with a respective physical vapor deposition technique, while being able to possibly correspond to a physical vapor deposition technique of one or more groups of physical vapor deposition techniques when at least one group of physical vapor deposition techniques is implemented simultaneously with the physical vapor deposition technique associated with the dedicated cathode.

In one embodiment, the deposition of the protective coating 16 is carried out by implementing simultaneously a first physical vapor deposition technique, a second physical vapor deposition technique, and a third different physical vapor deposition technique, the first physical vapor deposition technique and the second physical vapor deposition technique being implemented using a common cathode, the third technique being implemented using a dedicated cathode distinct from the common cathode.

In one embodiment, the deposition of the protective coating 16 is carried out by implementing simultaneously a first physical vapor deposition technique, a second physical vapor deposition technique, and a third different physical vapor deposition technique, the first physical vapor deposition technique and the second physical vapor deposition technique being implemented using a first common cathode, the first physical vapor deposition technique and the third physical vapor deposition technique being implemented using a second common cathode distinct from the first common cathode.

In one embodiment, the deposition of the protective coating 16 is carried out by implementing simultaneously a first physical vapor deposition technique, a second physical vapor deposition technique, and a third different physical vapor deposition technique, implemented respectively using a first dedicated cathode, a second dedicated cathode, and a third dedicated cathode.

In one embodiment, the deposition of the protective coating 16 is carried out by implementing simultaneously a first physical vapor deposition technique and a second physical vapor deposition technique, the first physical vapor deposition technique and the second physical vapor deposition technique being implemented using a common cathode, the first physical vapor deposition technique being implemented using a first dedicated cathode distinct from the common cathode, and, optionally, the second physical vapor deposition technique being implemented using a second dedicated cathode, distinct from the common cathode and the first dedicated cathode.

In the examples indicated above, the first physical vapor deposition technique, the second physical vapor deposition technique, and the third physical vapor deposition technique implemented simultaneously are, for example, chosen from among the high power impulse magnetron sputtering (HiPIMS) unipolar or bipolar, the direct current (DC) magnetron sputtering unipolar or bipolar, and the medium frequency (MF) magnetron sputtering unipolar or bipolar.

The examples indicated above are combinable for the simultaneous implementation of the first physical vapor deposition technique, the second physical vapor deposition technique, and the third physical vapor deposition technique implemented simultaneously.

Each one from among the first physical vapor deposition technique, the second physical vapor deposition technique, and the third physical vapor deposition technique can be implemented simultaneously using at least one common cathode and a dedicated cathode.

Furthermore, the present disclosure can be applied to substrates other than nuclear fuel rod cladding substrates.

When the substrate is symmetrical in revolution around a longitudinal axis, preferably, the physical vapor deposition is carried out by driving the substrate in rotation around its longitudinal axis to ensure uniform deposition on the circumference of the substrate.

Owing to the invention, it is possible to carry out the deposition of a protective coating quickly and better suited to the production of nuclear fuel rod claddings on an industrial scale.

The deposition speed of the protective coating using a physical vapor deposition technique by high power impulse magnetron sputtering (HiPIMS) and, simultaneously, another physical vapor deposition technique by cathodic sputtering, such as direct current (DC) magnetron sputtering or medium frequency (MF) magnetron sputtering, can be two to four times higher than the deposition speed using only the physical vapor deposition technique by high power impulse magnetron sputtering (HiPIMS), while maintaining the same deposition quality.

In particular, the use of at least one common cathode 26 allows to maximize the utilization time of the common cathode 26.

In particular, a common cathode 26 used for the implementation of a physical vapor deposition technique by high power impulse magnetron sputtering (HiPIMS) and, simultaneously, another physical vapor deposition technique by cathodic sputtering such as direct current (DC) magnetron sputtering or medium frequency (MF) magnetron sputtering, can be used with a higher utilization rate than if it were used only for the implementation of the physical vapor deposition technique by high power impulse magnetron sputtering (HiPIMS).

The time intervals between the high power pulses of the physical vapor deposition technique by high power impulse magnetron sputtering (HiPIMS) are indeed used for the implementation of said other physical vapor deposition technique by cathodic sputtering.

The combination of several techniques of physical vapor deposition by cathodic sputtering allows to benefit from the advantages of the different techniques, notably in terms of roughness of the protective coating 16, corrosion resistance of the protective coating 16, density of the protective coating 16, and/or adhesion of the protective coating 16 on the substrate 14.

Preferably, the deposition of the protective coating 16 is implemented so that the cladding 4 presents one or more of the following characteristics:
the roughness of the protective coating is equal to or less than 2 μm, particularly equal to or less than 1 μm;
the corrosion resistance of the protective coating 16 made of chrome-based material is such that the chromium oxide layer Cr₂O₃ is less than 1 μm after five years of use in the core of a nuclear reactor under normal (non-accidental) operation; and/or
the density of the protective coating is greater than 98%.

The density here refers to the percentage of the theoretical density of the same compact material, or as the theoretical density minus the porosity rate. A density greater than 98% corresponds to a porosity rate of less than 2%.

The quality of the adhesion between the substrate 14 and the protective coating 16 is tested, for example, by implementing an expansion due to compression test known by the acronym EDC for “Expansion Due to Compression”.

The combination of several physical vapor deposition techniques by cathodic sputtering allows to reduce the overall size of a physical vapor deposition installation, due to the reduction in the number of cathodes needed to achieve a desired productivity.

The table below presents the results of three examples provided as non-limiting examples and a comparative example.

TABLE 1

| | Example 1 | Example 2 | | |
|---|---|---|---|---|
| | 1 cathode | 1 cathode, | | |
| | 2 superposed | 2 superposed | Example 3 | Example 4 |
| | signals | signals | 2 cathodes | 1 cathode |
| | HiPIMS + | HiPIMS + | 1 signal/cathode | 1 signal |
| Parameter | DC | MF | HiPIMS + DC | HiPIMS |
| Chamber | 0.2 | 0.15 | 0.2 | 0.2 |
| pressure | | | | |
| (Pa) | | | | |
| Target- | 100 | 100 | 120 | 80 |
| substrate | | | | |
| distance | | | | |
| (mm) | | | | |
| Deposition | 6 | 5.5 | 7 | 2 |
| speed (μm/h) | | | | |
| HiPIMS | 85 | 80 | 70 | 70 |
| peak | | | | |
| power | | | | |
| density | | | | |
| (W/cm²) | | | | |
| HiPIMS | 4 | 4 | 6 | 9 |
| utilization | | | | |
| cycle (%) | | | | |
| DC power | 1 | — | 0.8 | — |
| density | | | | |
| (W/cm²) | | | | |
| DC | 78 | — | 100 | — |
| utilization | | | | |
| cycle (%) | | | | |
| MF power | — | 1.2 | — | — |
| density | | | | |
| (W/cm²) | | | | |
| Current | — | 20 | — | — |
| pulse | | | | |
| frequency | | | | |
| (kHz) | | | | |

In the first example (Example 1), a single cathode is used to simultaneously implement a physical vapor deposition by high power impulse magnetron sputtering (HiPIMS) and a physical vapor deposition by direct current (DC) magnetron sputtering, by applying two superposed signals to the cathode.

In the second example (Example 2), a single cathode is used to simultaneously implement a physical vapor deposition by high power impulse magnetron sputtering (HiPIMS) and a physical vapor deposition by medium frequency (MF) magnetron sputtering, by applying two superposed signals to the cathode.

In the third example (Example 3), two cathodes are used simultaneously, one to simultaneously implement a physical vapor deposition by high power impulse magnetron sputtering (HiPIMS); and the other to implement a physical vapor deposition by direct current (DC) magnetron sputtering. Each cathode receives an excitation signal corresponding to the respective physical vapor deposition technique.

In the fourth example (Example 4), which is a comparative example, a single cathode is used to implement a single physical vapor deposition technique, more particularly a high power impulse magnetron sputtering (HiPIMS).

The deposition speeds obtained in the first, second, and third examples are respectively 6 μm/h, 5.5 μm/h, and 7 μm/h, when the deposition speed achieved by implementing a single physical vapor deposition technique by cathodic sputtering would be of the order of 2 to 3 μm/h, as illustrated in the fourth example wherein the deposition speed is 2 μm/h.

What is claimed is:

1-17. (canceled)

18: A method for manufacturing a cladding of a nuclear fuel rod comprising a substrate covered with a protective coating, the method for manufacturing comprising:
providing the substrate; and
depositing the protective coating on the substrate by physical vapor deposition by cathodic sputtering, by implementing simultaneously several techniques of physical vapor deposition by cathodic sputtering, different from one another.

19: The method for manufacturing according to claim 18, wherein at least two from among the several techniques of physical vapor deposition by cathodic sputtering are implemented simultaneously using a common cathode.

20: The method for manufacturing according to claim 19, comprising an application to each common cathode of a combined excitation signal corresponding to a superposition of at least two elementary excitation signals, each elementary excitation signal being formed of a periodic pattern corresponding to a respective technique of physical vapor deposition by cathodic sputtering from among the techniques of physical vapor deposition by cathodic sputtering implemented simultaneously using said common cathode, the elementary excitation signals being synchronized in such a way that their respective patterns are present sequentially in the combined excitation signal.

21: The method for manufacturing according to claim 20, wherein each elementary excitation signal is generated by a respective excitation signal generator, the elementary excitation signals being synchronized and superposed to form the combined excitation signal applied to said common cathode.

22: The method for manufacturing according to claim 18, wherein at least one from among the techniques of physical vapor deposition by cathodic sputtering implemented simultaneously, is implemented using a dedicated cathode, by applying to this dedicated cathode an excitation signal for the implementation of this physical vapor deposition technique.

23: The method for manufacturing according to claim 18, wherein each from among the techniques of physical vapor deposition by cathodic sputtering implemented simultaneously, is implemented using a dedicated cathode, by applying to this dedicated cathode an excitation signal for the implementation of this technique of physical vapor deposition.

24: The method for manufacturing according to claim 22, wherein the excitation signal of each dedicated cathode is generated by a respective excitation signal generator.

25: The method for manufacturing according to claim 18, wherein the techniques of physical vapor deposition implemented simultaneously are chosen from a group consisting of: a high power impulse magnetron sputtering (HiPIMS) unipolar or bipolar, a direct current (DC) magnetron sputtering unipolar or bipolar, a pulsed direct current (pulsed-DC) magnetron sputtering unipolar or bipolar, a medium frequency (MF) magnetron sputtering unipolar or bipolar, and a radio frequency (RF) magnetron sputtering unipolar or bipolar.

26: The method for manufacturing according to claim 18, wherein the substrate is made of a zirconium-based material and/or the protective coating is made of a chrome-based material.

27: The method for manufacturing according to claim 18, wherein a thickness of the protective coating at an end of the depositing step is comprised between 5 μm and 30 μm.

28: The method for manufacturing according to claim 18, wherein a thickness of the protective coating at an end of the depositing step is comprised between 10 μm and 20 μm.

29: The method for manufacturing according to claim 18, wherein the substrate presents a shape of revolution around a central axis, the method for manufacturing comprises driving the substrate in rotation around the central axis during the depositing step.

30: The method for manufacturing according to claim 18, comprising polarizing the substrate during the deposition of the coating.

31: A nuclear fuel rod cladding comprising a substrate covered with a protective coating deposited on the substrate by physical vapor deposition by implementing simultaneously a plurality of different techniques of physical vapor deposition by cathodic sputtering.

32: A physical vapor deposition installation comprising:
a chamber;
at least one atmosphere control device to generate a rarefied atmosphere in the chamber;
at least one cathode; and
an excitation device,
the installation being configured for the deposition of a protective coating on a substrate introduced into the chamber by implementing simultaneously several different techniques of physical vapor deposition by cathodic sputtering using the at least one cathode.

33: The installation according to claim 32, comprising at least one common cathode for the simultaneous implementation of at least two from among the techniques of physical vapor deposition by cathodic sputtering implemented simultaneously, the excitation device being configured to generate a combined excitation signal of the common cathode which corresponds to the superposition of several elementary excitation signals, each elementary excitation signal having a periodic pattern corresponding to a respective, from among, the techniques of physical vapor deposition by cathodic sputtering implemented simultaneously using said common cathode, the elementary excitation signals being combined so that their respective patterns are present sequentially in the combined excitation signal.

34: The installation according to claim 32, comprising at least one dedicated cathode for the implementation of one from among the techniques of physical vapor deposition by cathodic sputtering implemented simultaneously, the excitation device being configured to generate a respective excitation signal for each dedicated cathode, the excitation signal corresponding to the technique of physical vapor deposition by cathodic sputtering associated with this dedicated cathode.

35: The installation according to claim 32, is configured for polarizing the substrate during the deposition of the coating.
